(19) United States
(12) Patent Application Publication
(10) Pub. No.: US 2025/0043411 A1
(43) Pub. Date: Feb. 6, 2025

(54) ION IMPLANTATION METHOD AND RELATED SYSTEMS

(71) Applicant: ENTEGRIS, INC., Billerica, MA (US)

(72) Inventor: Kaitlin J. Lawrence, Brookfield, CT (US)

(21) Appl. No.: 18/794,561

(22) Filed: Aug. 5, 2024

Related U.S. Application Data
(60) Provisional application No. 63/530,811, filed on Aug. 4, 2023.

(51) Int. Cl. C23C 14/48; C23C 14/14

(52) U.S. Cl. CPC C23C 14/48; C23C 14/14

(57) ABSTRACT

An ion implantation method and related systems are provided herein. The method of ion implantation comprises vaporizing a precursor comprising a metal borohydride compound to obtain a vaporized precursor, and contacting the vaporized precursor with a substrate, under vapor deposition conditions, to form a film on the substrate. The metal borohydride compound is isotopically enriched in at least one boron isotope.

### FIELD

The present disclosure relates to the field of ion implantation systems and methods.

### BACKGROUND

Precursors for ion implantation involves implantation of a chemical species into a substrate, such as a microelectronic device wafer, must have sufficient vapor pressure to produce enough ion current for deposition. Most metal precursors are solids that contain carbon and require heating. However, it is preferable to avoid carbon-based precursors and heating to prevent carbon deposit into the ion source beam, which decreases source life.

### SUMMARY

Some embodiments relate to a method of ion implantation. In some embodiments, the method of ion implantation comprises vaporizing a precursor comprising a metal borohydride compound to obtain a vaporized precursor, and contacting the vaporized precursor with a substrate, under vapor deposition conditions, to form a film on the substrate. In some embodiments, the metal borohydride compound is isotopically enriched in at least one boron isotope.

Some embodiments relate to a gas supply assembly. In some embodiments, the gas supply assembly comprises at least one gas supply vessel containing a precursor comprising a metal borohydride compound. In some embodiments, the metal borohydride compound is isotopically enriched in at least one boron isotope. In some embodiments, the at least one gas supply vessel is configured to vaporize the metal borohydride compound to produce a vaporized precursor for ion implantation into a substrate.

Some embodiments relate to an ion implantation system. In some embodiments, the ion implantation system comprises a gas supply assembly comprising at least one gas supply vessel in fluid communication with an ion implantation device. In some embodiments, the at least one gas supply vessel contains a precursor comprising a metal borohydride compound. In some embodiments, the metal borohydride compound is isotopically enriched in at least one boron isotope. In some embodiments, the at least one gas supply vessel is configured to vaporize the metal borohydride compound to produce a vaporized precursor that is supplied to the ion implantation device for ion implantation into a substrate.

### BRIEF DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 depicts a schematic representation of an ion implantation system, according to some embodiments.

FIG. 2 is a flow chart of a method for ion implantation, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure, which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “contacting” refers to bringing two or more components into immediate or close proximity, or into direct contact.

Some embodiments relate to ion implantation method and related systems. As disclosed herein, at least one advantage of the present disclosure is that the ion implantation method (and related systems) disclosed herein do not contain carbon and do not require heating in the ion implantation chamber. At least one additional advantage of the present disclosure is that the ion implantation method (and related systems) disclosed herein unexpectedly exhibit a longer source life. For example, as disclosed herein, in some embodiments, when the ion implantation methods (and related systems) employ a liquid aluminum precursor, such as aluminum borohydride, the ion implantation systems exhibit an enhanced ion beam current and/or source life.

Some embodiments relate to precursors and related methods. At least some of these embodiments relate to precursors useful in the fabrication of microelectronic devices, including semiconductor devices, and the like. For example, the precursors can be used to form films by one or more deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

As mentioned above, the precursor may include any source precursor, including vaporizable precursors. In some embodiments, the precursor comprises metal borohydride. In some embodiments, the metal borohydride compound is isotopically enriched in at least one boron isotope.

As used herein, “isotopically-enriched” may refer to a boron isotope. As another example, at least one boron isotope comprises ¹⁰B. As another example, at least one boron isotope comprises ¹¹B. As another example, at least one boron isotope comprises ¹⁰B and ¹¹B. As another example, at least one boron isotope comprises at least one of ¹⁰B, ¹¹B, or any combination thereof. Non-limiting examples of the isotopically-enriched metal borohydride compounds include, without limitation, at least one of KBH₄, Ca(BH₄)₂, LiBH₄, NaBH₄, Hf(BH₄)₄, Al(BH₄)₃, or any combination thereof. In some embodiments, the metal borohydride compound is a compound of the formula:

M(BH₄)ₙ,
where:
   M is K, Ca, Li, Na, Hf, or Al; and
   n is 0 to 4.

In some embodiments, the metal borohydride compound may comprise at least one of KBH₄, Ca(BH₄)₂, LiBH₄, NaBH₄, Hf(BH₄)₄, Al(BH₄)₃, or any combination thereof. In some embodiments, the at least one boron isotope comprises ¹⁰B. In some embodiments, the at least one boron isotope comprises ¹¹B. In some embodiments, the at least one boron isotope comprises ¹⁰B and ¹¹B. As another example, at least one boron isotope comprises at least one of ¹⁰B, ¹¹B, or any combination thereof.

In some embodiments, the purity of the metal borohydride compound is at least 90%. In some embodiments, the purity of the metal borohydride compound is at least 91%, 92%, 93%, 94%, 95%, 96%, 97%, 98%, 99%, 99.9%, 99.99%, 99.999%, or 99.9999%. In some embodiments, the purity of the metal borohydride compound is 100%.

In some embodiments, the precursor is present in a liquid phase.

In some embodiments, the precursor is vaporized at a temperature of 20° C. to 50° C. In some embodiments, the precursor is vaporized at a temperature of 25° C. to 50° C., 26° C. to 50° C., 27° C. to 50° C., 28° C. to 50° C., 29° C. to 50° C., 30° C. to 50° C., 31° C. to 50° C., 32° C. to 50° C., 33° C. to 50° C., 34° C. to 50° C., 35° C. to 50° C., 36° C. to 50° C., 37° C. to 50° C., 38° C. to 50° C., 39° C. to 50° C., 40° C. to 50° C., 41° C. to 50° C., 42° C. to 50° C., 43° C. to 50° C., 44° C. to 50° C., 45° C. to 50° C., 46° C. to 50° C., 47° C. to 50° C., 48° C. to 50° C., or 49° C. to 50° C. In some embodiments, the precursor is vaporized at a temperature of 20° C. to 49° C., 20° C. to 48° C., 20° C. to 47° C., 20° C. to 46° C., 20° C. to 45° C., 20° C. to 44° C., 20° C. to 43° C., 20° C. to 42° C., 20° C. to 41° C., 20° C. to 40° C., 20° C. to 39° C., 20° C. to 38° C., 20° C. to 37° C., 20° C. to 36° C., 20° C. to 35° C., 20° C. to 34° C., 20° C. to 33° C., 20° C. to 32° C., 20° C. to 31° C., 20° C. to 30° C., 20° C. to 29° C., 20° C. to 28° C., 20° C. to 27° C., 20° C. to 26° C., 20° C. to 25° C., 20° C. to 24° C., 20° C. to 23° C., 20° C. to 22° C., or 20° C. to 21° C.

In some embodiments, the precursor is vaporized at a temperature of 20° C. to 25° C. In some embodiments, the precursor is vaporized at a temperature of 21° C. to 25° C., 22° C. to 25° C., 23° C. to 25° C., or 24° C. to 25. In some embodiments, the precursor is vaporized at a temperature of 20° C. to 24, 20° C. to 23° C., 20° C. to 22° C., or 20° C. to 21° C.

In some embodiments, the precursor is vaporized at a pressure of 100 Torr to 800 Torr. In some embodiments, the precursor is vaporized at a pressure of 150 Torr to 800 Torr, 200 Torr to 800 Torr, 250 Torr to 800 Torr, 300 Torr to 800 Torr, 350 Torr to 800 Torr, 400 Torr to 800 Torr, 450 Torr to 800 Torr, 500 Torr to 800 Torr, 550 Torr to 800 Torr, 600 Torr to 800 Torr, 650 Torr to 800 Torr, 700 Torr to 800 Torr, or 750 Torr to 800 Torr. In some embodiments, the precursor is vaporized at a pressure of 100 Torr to 750 Torr, 100 Torr to 700 Torr, 100 Torr to 650 Torr, 100 Torr to 600 Torr, 100 Torr to 550 Torr, 100 Torr to 500 Torr, 100 Torr to 450 Torr, 100 Torr to 400 Torr, 100 Torr to 350 Torr, 100 Torr to 300 Torr, 100 Torr to 250 Torr, 100 Torr to 200 Torr, or 100 Torr to 150 Torr.

In some embodiments, the precursor is vaporized at a pressure of 740 Torr to 780 Torr. In some embodiments, the precursor is vaporized at a pressure of 740 Torr to 780 Torr, 745 Torr to 780 Torr, 750 Torr to 780 Torr, 755 Torr to 780 Torr, 760 Torr to 780 Torr, 765 Torr to 780 Torr, 770 Torr to 780 Torr, or 775 Torr to 780 Torr. In some embodiments, the precursor is vaporized at a pressure of 740 Torr to 775 Torr, 740 Torr to 770 Torr, 740 Torr to 765 Torr, 740 Torr to 760 Torr, 740 Torr to 755 Torr, 740 Torr to 750 Torr, or 740 Torr to 745 Torr.

In some embodiments, the precursor or the vaporized precursor further comprises H₂.

In some embodiments, the precursor or the vaporized precursor further comprises at least one of BF₃, BH₃, B₂H₆, or any combination thereof.

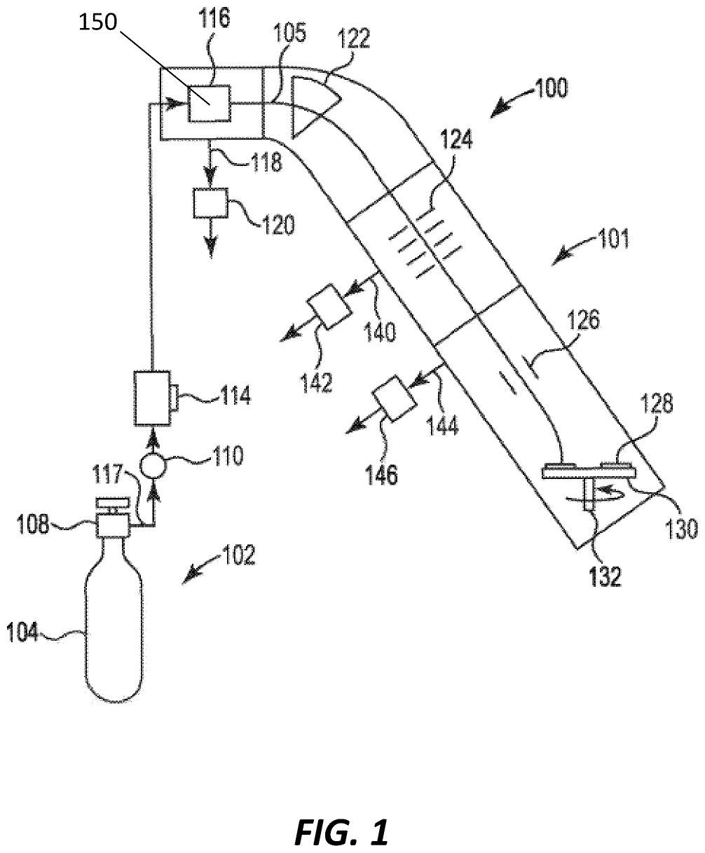

FIG. 1 depicts a schematic representation of an ion implantation system, according to some embodiments. In some embodiments, the gas component supplied from the at least one gas supply vessel 102 to the arc chamber 150 for implantation into a substrate contains a precursor comprising a metal borohydride compound. In some embodiments, the metal borohydride compound is isotopically enriched in at least one boron isotope. In some embodiments, the at least one gas supply vessel 102 is configured to vaporize the metal borohydride compound to produce a vaporized precursor for ion implantation into a substrate.

In some embodiments, the metal borohydride compound of the gas supply assembly and/or the at least one gas supply vessel 102 comprises at least one of KBH₄, Ca(BH₄)₂, LiBH₄, NaBH₄, Hf(BH₄)₄, Al(BH₄)₃, or any combination thereof. In some embodiments, the at least one boron isotope comprises at least one of ¹⁰B, ¹¹B, or any combination thereof.

In some embodiments, the at least one gas supply vessel 102 is a single vessel. In some embodiments, the at least one gas supply vessel 102 comprises two or more vessels. In some embodiments, the at least one gas supply vessel 102 comprises at least one of a first vessel, a second vessel, a third vessel, a fourth vessel, or any combination thereof. It will be appreciated that any one of the at least one gas supply vessels 102 disclosed herein may further comprise other gases and/or materials, such as, for example and without limitation, at least one of an ionizable gas, a diluent gas, a carrier gas, a co-gas, the like, or any combination thereof. In some embodiments, the gas supply vessel 102 comprises a single vessel comprising a precursor. In some embodiments, the precursor comprises a metal borohydride compound. In some embodiments, the metal borohydride compound is isotopically-enriched.

In some embodiments, an individual vessel of one or more vessels comprises more than one dopant gas, such that the vessel comprises a mixture of dopant gases. In some embodiments, the gas supply vessel 102 is configured to deliver a dopant gas subatmospherically via one or more pressure reduction regulators. In some embodiments, a dopant gas is delivered subatmospherically through the use of an adsorbent.

In some embodiments, the arc chamber 150 includes arc chamber walls with interior-plasma facing surfaces. There may be one or more arc chamber liners configured to contact all or a portion of the interior-plasma facing surfaces of the walls of the arc chamber 150.

As shown in FIG. 1, the gas supply vessel 102 may have an interior volume holding a precursor comprising a metal borohydride compound, that is supplied for ion implantation of a substrate 128 in the illustrated ion implant chamber 101. In some embodiments, the metal borohydride compound is isotopically enriched in at least one boron isotope. In some embodiments, the metal borohydride compound comprises at least one of KBH₄, Ca(BH₄)₂, LiBH₄, NaBH₄, Hf(BH₄)₄, Al(BH₄)₃, or any combination thereof. In some embodiments, the at least one boron isotope comprises at least one of ¹⁰B, ¹¹B, or any combination thereof.

The storage and gas supply vessel 102 may be of a type containing a sorbent medium on which the dopant gas is physically adsorbed for storage of the gas, with the gas being desorbed from the sorbent medium, under dispensing conditions, for discharge from the gas supply vessel 102. The sorbent medium may be a solid-phase carbon adsorbent material. Sorbent-based vessels of such type are commercially available from Entegris. Inc. (Danbury, Conn., USA) under the trademarks SDS and SAGE. Alternatively, the vessel may be of an internally pressure-regulated type, containing one or more pressure regulators in the interior volume of the vessel. Such pressure-regulated vessels are commercially available from Entegris, Inc. (Danbury, Conn., USA) under the trademark VAC. As a still further alternative, the vessel may contain the dopant source material in a solid form that is volatilized, e.g., by heating of the vessel and/or its contents, to generate the dopant gas as a vaporization or sublimation product.

The storage and gas supply vessel 102 may include a cylindrical vessel wall 104 enclosing an interior volume holding the metal borohydride compound in an adsorbed state, a free gas state, or a liquefied gas state, or a mixture thereof.

The gas supply vessel 102 may include a valve head 108 coupled in gas flow communication via a dispensing line 117. A pressure sensor 110 may be disposed in the line 117, together with a mass flow controller 114; other optional monitoring and sensing components may be coupled with the line, and interfaced with control means such as actuators, feedback and computer control systems, cycle timers, etc.

The ion implant chamber 101 may contain an ion source 116 receiving the dispensed precursor from line 117 and generates an ion beam 105. The ion beam 105 may pass through the mass analyzer unit 122 which selects the ions needed and rejects the non-selected ions.

The selected ions may pass through the acceleration electrode array 124 and then the deflection electrodes 126. The resulting focused ion beam may be impinged on the substrate element 128 disposed on the rotatable holder 130 mounted on spindle 132. The ion beam of dopant ions may be used to dope the substrate as desired to form a doped structure.

The respective sections of the ion implant chamber 101 may be exhausted through lines 118, 140 and 144 by means of pumps 120, 142 and 146, respectively.

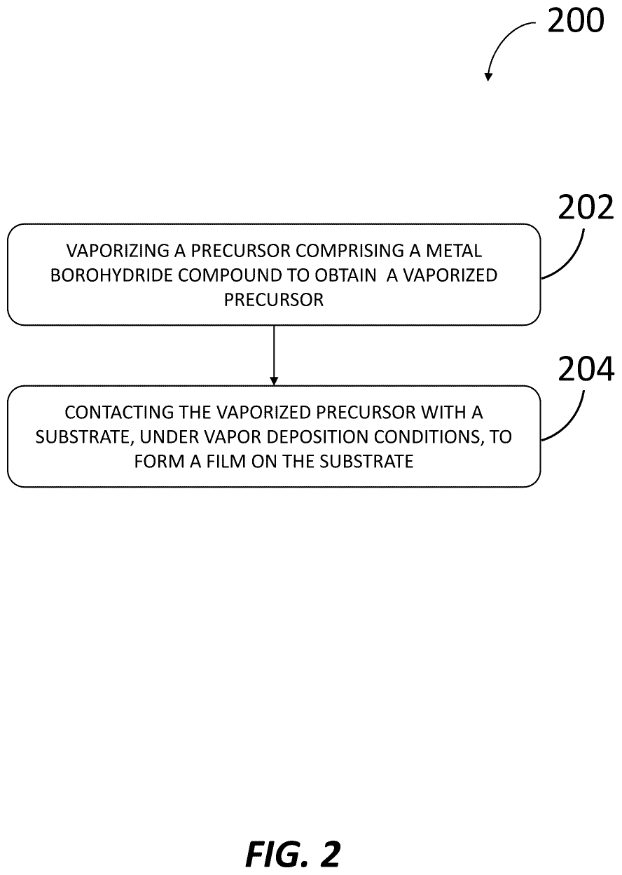

FIG. 2 is a flow chart of a method 200 for ion implantation, according to some embodiments.

As shown in FIG. 2, the method 200 may comprise one or more of the following steps: a step 202 of vaporizing a precursor comprising a metal borohydride compound to obtain a vaporized precursor; and a step 204 of contacting the vaporized precursor with a substrate, under vapor deposition conditions, to form a film on the substrate. In some embodiments, the metal borohydride compound is isotopically enriched in at least one boron isotope. In some embodiments, the metal borohydride compound comprises at least one of KBH₄, Ca(BH₄)₂, LiBH₄, NaBH₄, Hf(BH₄)₄, Al(BH₄)₃, or any combination thereof. In some embodiments, the at least one boron isotope comprises at least one of ¹⁰B, ¹¹B, or any combination thereof.

In some embodiments, the vaporizing of step 202 comprises heating the precursor, sputtering the precursor with a reactive gas, vaporizing the precursor at a pressure, or vaporizing the precursor at a pressure and temperature.

In some embodiments, the arc chamber of step 202 may be the arc chamber 150 as described herein. The gas component may comprise the precursor of the gas supply vessel 102 as described herein.

In some embodiments, the contacting of step 204 comprises reacting the vaporized precursor with the substrate. In some embodiments, the contacting comprises mixing the vaporized precursor and the substrate. In some embodiments, the contacting comprises absorbing the vaporized precursor on the substrate. In some embodiments, the contacting comprises combining the vaporized precursor and the substrate. In some embodiments, the contacting is performed under vapor conditions. In some embodiments, the contacting forms a film on the substrate.

It will be appreciated that any one or more of the embodiments disclosed herein may be employed in alone or in combination, without departing from the scope of this disclosure.

### ASPECTS

Various Aspects are described below. It is to be understood that any one or more of the features recited in the following Aspect(s) can be combined with any one or more other Aspect(s).

Aspect 1. A method of ion implantation, comprising:
vaporizing a precursor comprising a metal borohydride compound to obtain a vaporized precursor,
wherein the metal borohydride compound is isotopically enriched in at least one boron isotope; and
contacting the vaporized precursor with a substrate, under vapor deposition conditions, to form a film on the substrate.

Aspect 2. The method according to Aspect 1, wherein the metal borohydride compound is a compound of the formula:

M(BH₄)ₓ,
where:
   M is K, Ca, Li, Na, Hf, or Al; and
      n is 0 to 4.

Aspect 3. The method according to any one of Aspects 1-2, wherein the metal borohydride compound comprises at least one of KBH₄, Ca(BH₄)₂, LiBH₄, NaBH₄, Hf(BH₄)₄, Al(BH₄)₃, or any combination thereof.

Aspect 4. The method according to any one of Aspects 1-3, wherein the at least one boron isotope comprises ¹⁰B.

Aspect 5. The method according to any one of Aspects 1-4, wherein the at least one boron isotope comprises ¹¹B.

Aspect 6. The method according to any one of Aspects 1-5, wherein the at least one boron isotope comprises ¹⁰B and ¹¹B.

Aspect 7. The method according to any one of Aspects 1-6, wherein a purity of the metal borohydride compound is at least 90%.

Aspect 8. The method according to any one of Aspects 1-7, wherein the precursor is present in a liquid phase.

Aspect 9. The method according to any one of Aspects 1-8, wherein the precursor is vaporized at a temperature of 20° C. to 50° C.

Aspect 10. The method according to any one of Aspects 1-9, wherein the precursor is vaporized at a temperature of 20° C. to 25° C.

Aspect 11. The method according to any one of Aspects 1-10, wherein the precursor is vaporized at a pressure of 100 Torr to 800 Torr.

Aspect 12. The method according to any one of Aspects 1-11, wherein the precursor is vaporized at a pressure of 740 Torr to 780 Torr.

Aspect 13. The method according to any one of Aspects 1-12, wherein the precursor further comprises H₂.

Aspect 14. The method according to any one of Aspects 1-13, wherein the precursor further comprises at least one of BF₃, BH₃, B₂H₆, or any combination thereof.

Aspect 15. A gas supply assembly comprising:
at least one gas supply vessel containing a precursor comprising a metal borohydride compound,
   wherein the metal borohydride compound is isotopically enriched in at least one boron isotope;
   wherein the at least one gas supply vessel is configured to vaporize the metal borohydride compound to produce a vaporized precursor for ion implantation into a substrate.

Aspect 16. The gas supply assembly according to Aspect 15, wherein the metal borohydride compound comprises at least one of KBH₄, Ca(BH₄)₂, LiBH₄, NaBH₄, Hf(BH₄)₄, Al(BH₄)₃, or any combination thereof.

Aspect 17. The gas supply assembly according to any one of Aspects 15-16, wherein the at least one boron isotope comprises at least one of ¹⁰B, ¹¹B, or any combination thereof.

Aspect 18. An ion implantation system comprising:
a gas supply assembly comprising at least one gas supply vessel in fluid communication with an ion implantation device,
   wherein the at least one gas supply vessel contains a precursor comprising a metal borohydride compound;
      wherein the metal borohydride compound is isotopically enriched in at least one boron isotope;
      wherein the at least one gas supply vessel is configured to vaporize the metal borohydride compound to produce a vaporized precursor that is supplied to the ion implantation device for ion implantation into a substrate.

Aspect 19. The ion implantation system according to Aspect 18, wherein the metal borohydride compound comprises at least one of KBH₄, Ca(BH₄)₂, LiBH₄, NaBH₄, Hf(BH₄)₄, Al(BH₄)₃, or any combination thereof.

Aspect 20. The ion implantation system according to any one of Aspects 18-19, wherein the at least one boron isotope comprises at least one of ¹⁰B, ¹¹B, or any combination thereof.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A method of ion implantation, comprising:
vaporizing a precursor comprising a metal borohydride compound to obtain a vaporized precursor;
wherein the metal borohydride compound is isotopically enriched in at least one boron isotope; and
contacting the vaporized precursor with a substrate, under vapor deposition conditions, to form a film on the substrate.

2. The method of claim 1, wherein the metal borohydride compound is a compound of the formula:
M(BH₄)ₙ,
where:
M is K, Ca, Li, Na, Hf, or Al; and
n is 0 to 4.

3. The method of claim 1, wherein the metal borohydride compound comprises at least one of KBH₄, Ca(BH₄)₂, LiBH₄, NaBH₄, Hf(BH₄)₄, Al(BH₄)₃, or any combination thereof.

4. The method of claim 1, wherein the at least one boron isotope comprises ¹⁰B.

5. The method of claim 1, wherein the at least one boron isotope comprises ¹¹B.

6. The method of claim 1, wherein the at least one boron isotope comprises ¹⁰B and ¹¹B.

7. The method of claim 1, wherein a purity of the metal borohydride compound is at least 90%.

8. The method of claim 1, wherein the precursor is present in a liquid phase.

9. The method of claim 1, wherein the precursor is vaporized at a temperature of 20° C. to 50° C.

10. The method of claim 1, wherein the precursor is vaporized at a temperature of 20° C. to 25° C.

11. The method of claim 1, wherein the precursor is vaporized at a pressure of 100 Torr to 800 Torr.

12. The method of claim 1, wherein the precursor is vaporized at a pressure of 740 Torr to 780 Torr.

13. The method of claim 1, wherein the precursor further comprises H₂.

14. The method of claim 1, wherein the precursor further comprises at least one of BF₃, BH₃, B₂H₆, or any combination thereof.

15. A gas supply assembly comprising:
at least one gas supply vessel containing a precursor comprising a metal borohydride compound,
wherein the metal borohydride compound is isotopically enriched in at least one boron isotope;
wherein the at least one gas supply vessel is configured to vaporize the metal borohydride compound to produce a vaporized precursor for ion implantation into a substrate.

16. The gas supply assembly of claim 15, wherein the metal borohydride compound comprises at least one of KBH₄, Ca(BH₄)₂, LiBH₄, NaBH₄, Hf(BH₄)₄, Al(BH₄)₃, or any combination thereof.

17. The gas supply assembly of claim 15, wherein the at least one boron isotope comprises at least one of ¹⁰B, ¹¹B, or any combination thereof.

18. An ion implantation system comprising:
a gas supply assembly comprising at least one gas supply vessel in fluid communication with an ion implantation device,
wherein the at least one gas supply vessel contains a precursor comprising a metal borohydride compound;
wherein the metal borohydride compound is isotopically enriched in at least one boron isotope;
wherein the at least one gas supply vessel is configured to vaporize the metal borohydride compound to produce a vaporized precursor that is supplied to the ion implantation device for ion implantation into a substrate.

19. The ion implantation system of claim 18, wherein the metal borohydride compound comprises at least one of KBH₄, Ca(BH₄)₂, LiBH₄, NaBH₄, Hf(BH₄)₄, Al(BH₄)₃, or any combination thereof.

20. The ion implantation system of claim 18, wherein the at least one boron isotope comprises at least one of ¹⁰B, ¹¹B, or any combination thereof.
